(19) United States
(12) Patent Application Publication
(10) Pub. No.: US 2024/0373588 A1
(43) Pub. Date: Nov. 7, 2024

(54) HEAT DISSIPATION APPARATUS AND ELECTRONIC DEVICE

(71) Applicant: ZTE CORPORATION, Shenzhen (CN)

(72) Inventors: Zhenjie LI, Shenzhen (CN); Fan LIU, Shenzhen (CN); Haolong FAN, Shenzhen (CN)

(21) Appl. No.: 18/291,775

(22) PCT Filed: Mar. 2, 2022
(86) PCT No.: PCT/CN2022/078896

§ 371 Date: Jan. 24, 2024

(30) Foreign Application Priority Data
Jul. 28, 2021 (CN) 202110859071.7

(51) Int. Cl. H05K 7/20

(52) U.S. Cl. CPC H05K 7/20272; H05K 7/20254; H05K 7/20263; H05K 7/20454; H05K 7/20472; H05K 7/2049

(57) ABSTRACT

Disclosed are a heat dissipation apparatus and an electronic device. The heat dissipation apparatus includes a first cooling plate, provided with a through hole arranged to be connected to an inlet pipe and an outlet pipe; a second cooling plate, with a heat dissipation cavity formed between the first cooling plate and the second cooling plate and in communication with the through hole; and a retractable floating component, connected to the second cooling plate for floating heat dissipation of the second cooling plate.

### CROSS-REFERENCE TO RELATED APPLICATION

This application is a national stage filing under 35 U.S.C. § 371 of international application number PCT/CN2022/078896, filed Mar. 2, 2022, which claims priority to Chinese patent application No. 202110859071.7 filed Jul. 28, 2021. The contents of these applications are incorporated herein by reference in their entirety.

### TECHNICAL FIELD

The present disclosure relates to the technical field of heat dissipation apparatuses and, in particular, to a heat dissipation apparatus and an electronic device.

### BACKGROUND

With the rapid development of electronic technology, the power consumption and heat dissipation of electronic elements is also continuously improved, so in order to improve the operating efficiency of electronic devices and protect electronic elements to enable their normal operation, it is often necessary to cool down the electronic elements in operation, and indirect liquid cooling technology is one of the ways to reduce the temperature. In the fast-developing indirect liquid cooling technology, the surfaces of electronic elements are affixed to the surface of the liquid cooling plate, so that the heat of the electronic elements is transferred to the liquid cooling plate through heat conduction, and strong and effective convective heat exchange takes place between the liquid cooling plate and the working medium to take away the heat. In some cases, a fluid-containing cooling plate is provided as a heat dissipation apparatus for indirect liquid cooling of the electronic elements, but in some cases, the heat dissipation apparatus has the disadvantages of poor floatability and low reliability, and cannot stably contact the electronic elements, and therefore cannot effectively cool the electronic elements.

### SUMMARY

The following is a summary of the subject matters described in detail herein. This summary is not intended to limit the scope of protection of the claims.

Embodiments of the present disclosure provide a heat dissipation apparatus and an electronic device.

In accordance with a first aspect of the present disclosure, an embodiment provides a heat dissipation apparatus, including: a first cooling plate, provided with a through hole arranged to be connected to an inlet pipe and an outlet pipe; a second cooling plate, with a heat dissipation cavity formed between the first cooling plate and the second cooling plate and in communication with the through hole; and a retractable floating component, connected to the second cooling plate for floating heat dissipation of the second cooling plate.

In accordance with a second aspect of the present disclosure, an embodiment further provides an electronic device, including a heat dissipation apparatus as described in any one of embodiments of the first aspect of the present disclosure.

Additional features and advantages of the present disclosure will be set forth in the subsequent description, and in part will become apparent from the description, or may be learned by practice of the present disclosure. The purposes and other advantages of the present disclosure can be realized and obtained by structures particularly noted in the description, the claims and the accompanying drawings.

### BRIEF DESCRIPTION OF DRAWINGS

The accompanying drawings are used to provide further understanding of the technical schemes of the present disclosure and constitute a part of the description. The accompanying drawings are used to explain the technical schemes of the present disclosure together with the embodiments of the present disclosure, and do not constitute a restriction on the technical schemes of the present disclosure.

FIG. 1 is a schematic diagram of the internal structure of a heat dissipation apparatus provided in an embodiment of the present disclosure;

FIG. 2 is a schematic diagram of the internal structure of a heat dissipation apparatus provided in another embodiment of the present disclosure;

FIG. 3 is a schematic diagram of the internal structure of a heat dissipation apparatus provided in another embodiment of the present disclosure;

FIG. 4 is an overall schematic diagram of a heat dissipation apparatus provided in an embodiment of the present disclosure;

FIG. 5 is an overall schematic diagram of a heat dissipation apparatus provided in another embodiment of the present disclosure;

FIG. 6 is a connection schematic diagram of a heat dissipation apparatus provided in an embodiment of the present disclosure;

FIG. 7 is a schematic diagram of a floating change of a heat dissipation apparatus provided in an embodiment of the present disclosure;

FIG. 8 is a schematic diagram of the internal structure of a heat dissipation apparatus provided in another embodiment of the present disclosure;

FIG. 9 is a schematic diagram of the internal structure of a heat dissipation apparatus provided in another embodiment of the present disclosure;

FIG. 10 is a schematic diagram of the internal structure of a heat dissipation apparatus provided in another embodiment of the present disclosure;

FIG. 11 is a schematic diagram of the internal structure of a heat dissipation apparatus provided in another embodiment of the present disclosure;

FIG. 12 is a schematic diagram of the internal structure of a floating component provided in an embodiment of the present disclosure; and

FIG. 13 is a schematic diagram of the internal structure of a heat dissipation apparatus provided in another embodiment of the present disclosure.

### LIST OF REFERENCE NUMERALS

First cooling plate 110; through hole 111; inlet pipe 1111; outlet pipe 1112; protruding portion 112; first groove 113; second cooling plate 120; first surface 121; second surface 122; heat dissipation teeth 123; flow channel 124; heat dissipation cavity 125; second groove 126; fixing hole 127; floating component 130; housing 131; elastic element 132; braided layer 133; elastic sheet 140; pipeline 150; single board element 160; interface material 170.

### DETAILED DESCRIPTION

In order to make the objectives, technical schemes and advantages of the present disclosure more apparent, the present disclosure is further described in detail in conjunction with the accompanying drawings and embodiments. It should be understood that the particular embodiments described herein are only intended to explain the present disclosure, and are not intended to limit the present disclosure.

It should be known that, in the description of the embodiments of the present disclosure, “plurality (or multiple)” means two or more; “greater than”, “less than”, “over”, etc. are to be understood to exclude the given figure; and “above”, “below”, “within”, etc. are understood to include the given figure. If “first” and “second”, etc. are referred to, it is only for the purpose of distinguishing technical features, and shall not be understood as indicating or implying relative importance or implying the number of the indicated technical features or implying the sequence of the indicated technical features.

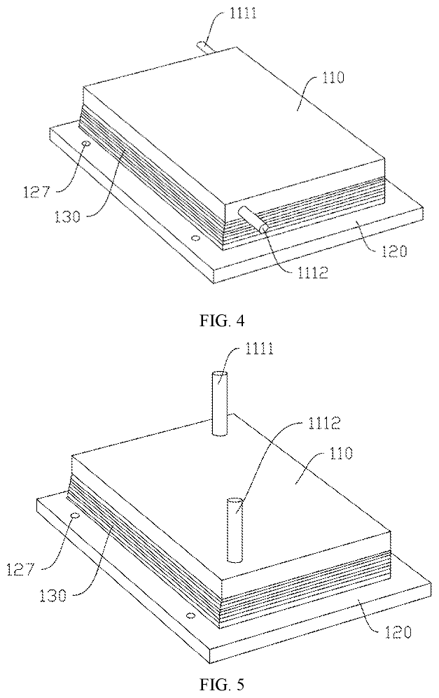

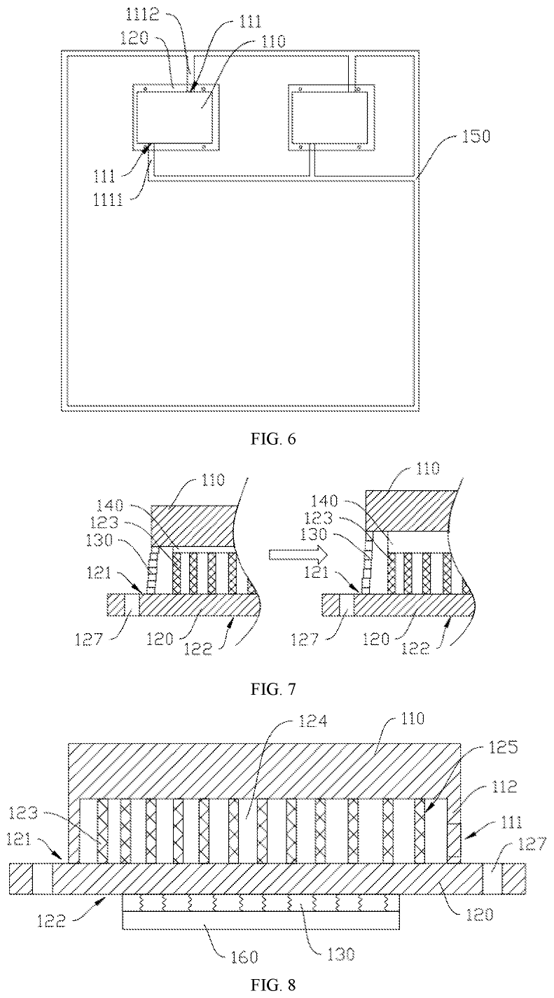

Referring to FIGS. 1 to 3, in some embodiments of the present disclosure provided is a heat dissipation apparatus including a first cooling plate 110, a second cooling plate 120, and a floating component 130, where the floating component 130 is retractable and thus has the capability of retractable adjustment, and the floating component 130 is connected to the second cooling plate 120 for floating heat dissipation of the second cooling plate 120. One of the first cooling plate 110 and the second cooling plate 120 may be a cooling plate substrate, and the other one may be a cooling plate cover. In an embodiment of the present disclosure, the first cooling plate 110 is the cooling plate cover, the second cooling plate 120 is the cooling plate substrate arranged to be in contact with an electronic element such as a single board element 160. The electronic element may be a single board element 160, a battery, an optical module, or the like, and the single board element 160 may include a single board, a chip, or the like. The single board element 160 is taken as an example for illustration in embodiments of the present disclosure, which, however, is not meant to be a limitation of the present disclosure. Here, the first cooling plate 110 is provided with through holes 111, and with reference to FIGS. 4 and 5, the through holes 111 can be connected to at least one inlet pipe 1111 and at least one outlet pipe 1112. A heat dissipation cavity 125 is formed between the first cooling plate 110 and the second cooling plate 120, and the heat dissipation cavity 125 is in communication with the through holes 111. Referring to FIG. 6, in an embodiment, the through holes 111 may be connected to a pipeline 150, and the inlet pipe 1111 and the outlet pipe 1112 may be part of the pipeline 150 or may be respectively connected to the pipeline 150. Fluid may enter one of the through holes 111 from the inlet pipe 1111 of the pipeline 150, flow through the flow channel 124, and finally flows out of the outlet pipe 1112 through another through hole 111. By means of the floating component 130, according to the reaction force of the pipeline 150 between the cooling plates due to the height difference and/or tolerance, the floating component 130 is connected to the second cooling plate 120 and can retractably adjust the spacing between the second cooling plate 120 and the first cooling plate 110 or the spacing between the second cooling plate 120 and the single board element 160, thereby ensuring that the second cooling plate 120 and the single board element 160 are always in reliable contact. The heat dissipation apparatus in embodiments of the present disclosure has good floatability and high reliability, and is therefore capable of making stable contact with electronic elements, such as the single board element 160, in order to efficiently cool the electronic elements.

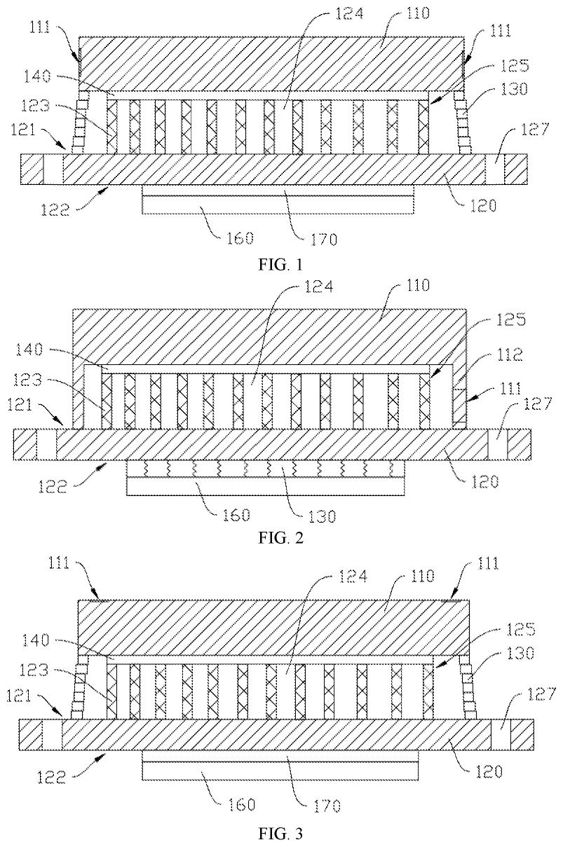

In some embodiments of the present disclosure, referring to FIG. 1, the floating component 130 is connected to the first cooling plate 110 and the second cooling plate 120 respectively, the heat dissipation cavity 125 is provided on a first surface 121 of the second cooling plate 120, and the floating component 130 is provided on at least one side of the heat dissipation cavity 125, thereby ensuring a floating connection between the first cooling plate 110 and the second cooling plate 120. Referring to FIG. 2, the floating component 130 may also be provided on a second surface 122 of the second cooling plate 120 opposite to the first surface 121, i.e., the first surface 121 and the second surface 122 are opposite sides of the second cooling plate 120. In an embodiment, the floating component 130 may be provided alone between the first cooling plate 110 and the second cooling plate 120, and in another embodiment, the floating component 130 may be provided alone on the second surface 122 of the second cooling plate 120, and in yet another embodiment, the floating components 130 may be provided at both of the above positions, i.e., one floating component 130 is provided between the first cooling plate 110 and the second cooling plate 120, and another floating component 130 is provided on the second surface 122 of the second cooling plate 120. In the embodiments of the present disclosure, the heat dissipation apparatus, by means of the application of the floating component 130, ensures that the second cooling plate 120 is always in reliable and stable contact with the single board element 160 by adjusting the floating component 130 of the second cooling plate 120 and the first cooling plate 110 during mounting and operation of the heat dissipation apparatus, so as to effectively dissipate heat for the single board element 160, thereby better enabling the heat dissipation apparatus to be stably connected to the single board element 160.

Referring to FIG. 1, in some embodiments of the present disclosure, the second cooling plate 120 is provided with heat dissipation teeth 123 on the first surface 121 thereof, and the heat dissipation teeth 123 may be provided on the second cooling plate 120 separately or may be integrally formed with the second cooling plate 120. The second cooling plate 120 is in contact with the single board element 160 to receive heat from the single board element 160 and convectively transfer the heat into the cooling medium in the heat dissipation cavity 125. It is to be noted that the heat dissipation cavity 125 is formed between the first cooling plate 110 and the second cooling plate 120, and the heat dissipation teeth 123 are disposed in the heat dissipation cavity 125. Flow channels 124 are formed between the gaps of the heat dissipation teeth 123, and in communication with the through holes 111 to allow the fluid to flow from the through holes 111 into the flow channels 124, i.e., flowing through the gaps between the heat dissipation teeth 123, to take away the heat from the electronic element such as the single board element 160 through efficient convective heat exchanges, where the flow channels 124 may be filled with a fluid, such as a coolant, as the cooling medium.

It is to be noted that the fluid in some embodiments of the present disclosure may be a fluorinated fluid, a water-like or water-glycol-like single-phase cooling working medium, etc., or a phase-change working medium such as R134a, etc., which can be used for cooling. The heat dissipation apparatus may be applied in a purely liquid-cooled heat dissipation system or in an air-liquid-mixed heat dissipation system, and the embodiments of the present disclosure do not impose specific limitations thereon. The second cooling plate 120 may be provided with several fixing holes 127, the fixing holes 127 may be screw holes or rivet holes, etc., and the heat dissipation apparatus may be fixedly mounted on the single board element 160 or other devices through the fixing holes 127, and the flow channels 124 between the gaps of the heat dissipation teeth 123 may be flow channels 124 in the form of relieving teeth, milled channels, or spoilers, etc., and are suitable for use in various forms of cooling plates such as milled channels or micro-channels.

Referring to FIG. 6, it is to be noted that in an application scenario of the heat dissipation apparatus, the pipeline 150 is connected to a plurality of heat dissipation apparatuses to mount each of the heat dissipation apparatuses correspondingly to a single board element 160 in the device, and the pipeline 150 may be provided with a plurality of mother channels and child channels, where the mother channels are in communication with the child channels, a mother channel may be connected to a plurality of child channels and connected to the inlet pipes 1111 of the various heat dissipation apparatuses through the child channels, and after the outlet pipes 1112 within the heat dissipation apparatuses, the plurality of child channels are then converged to a mother channel. The heat dissipation apparatuses are connected to each other through the pipeline 150 to form a series-parallel fluid loop and the inlet and outlet of the pipeline 150 are connected to the external environment to form a closed loop. In an embodiment, a plurality of single board elements 160 are included in the device, and there is a certain height tolerance between the single board elements 160 due to the height differences or tolerances of the single board elements 160, whereas the first cooling plates 110 of the plurality of heat dissipation apparatuses are always kept in reliable contact with the corresponding single board elements 160 and are connected via the pipeline 150. By means of the design of the floating component 130 in each heat dissipation apparatus, the reaction force brought about by the pipeline 150 due to the height tolerance is solved, thus realizing a stable and reliable connection with the plurality of single board elements 160 in the device, which enables not only a high pressure-resistant capacity and no risk of leakage, but also a simple structure, thus saving a large amount of hardware design costs, and also greatly reduces the extra space inside the device designed for heat dissipation due to the small size of the heat dissipation apparatus, thus enabling an obvious heat dissipation effect.

It is to be noted that in some embodiments of the present disclosure, referring to FIGS. 1 and 4, the through hole 111 may be provided on the lateral sides of the first cooling plate 110, and, referring to FIGS. 3 and 5, it may be provided on the top of the first cooling plate 110. In other words, at least one of the inlet pipe 1111 and the outlet pipe 1112 may be provided on the lateral sides of the first cooling plate 110, or that at least one of the inlet pipe 1111 and the outlet pipe 1112 may be provided on the top of the first cooling plate 110. This may be reasonably selected according to the specific application scenario, and the embodiments of the present disclosure do not impose specific limitations thereon.

Referring to FIGS. 1 and 2, it is to be noted that in some embodiments of the present disclosure, in the case where the floating component 130 is connected to the first cooling plate 110 and the second cooling plate 120 respectively, the second cooling plate 120 may be in direct contact with the single board element 160, or by providing an interface material 170 on the single board element 160, the second cooling plate 120 is connected to the interface material 170. In the case where the floating component 130 is provided on the second surface 122 of the second cooling plate 120, the floating component 130 may be in direct contact with the single board element 160, or by providing the interface material 170 on the single board element 160, the floating component 130 is connected to the interface material 170, where the interface material 170 may be of a high-tolerance interface material 170, and embodiments of the present disclosure do not impose specific limitations thereon.

Referring to FIGS. 1 and 2, in some embodiments of the present disclosure, a retractable elastic sheet 140 is included, one end of the elastic sheet 140 is connected to the heat dissipation teeth 123, i.e., the tooth tips of the heat dissipation teeth 123, and the other end of the elastic sheet 140 is connected to the first cooling plate 110. Referring to FIG. 7, when the floating component 130 deforms, in order to ensure the close contact of the tooth tips of the heat dissipation teeth 123 to the first cooling plate 110, and to prevent the fluid from flowing out from the gap between the tooth tips and the first cooling plate 110, the elastic sheet 140 that is retractable and deformable is designed. The elastic sheet 140 is a structure having a certain elastic deformation capacity, and the material and shape thereof are not limited. For example, a plurality of elastic elements may be provided within the elastic sheet 140 so that a certain elastic deformation capacity can be realized. In an embodiment, in the case where the floating component 130 is connected to the first cooling plate 110 and the second cooling plate 120 respectively, the fluid in the pipeline 150 applies a certain intensity of pressure to the heat dissipation cavity 125 and applies an acting force to the floating component 130, and thus the elasticity of the elastic sheet 140 is preferable to the amount of deformation of the floating component 130 under the counterforce of the pipeline 150, so that the heat dissipation apparatus has a better stability.

Referring to FIG. 8, it is to be noted that in the case where the floating component 130 is provided on the second surface 122 of the second cooling plate 120, the elastic sheet 140 may not be provided between the first cooling plate 110 and the heat dissipation teeth 123, and the floating connection between the heat dissipation apparatus and the single board element 160 can be realized by providing the floating component 130 on the second surface 122 alone.

Referring to FIGS. 4 and 5, in some embodiments of the present disclosure, in the case where the floating component 130 is separately made and assembled to the first cooling plate 110 and the second cooling plate 120, the floating component 130 is provided surrounding the perimeter of the heat dissipation cavity 125. In an embodiment, the floating component 130 is disposed at least on one side of the heat dissipation cavity 125, and for better floatability and improve stability, the floating component 130 may be disposed on opposite sides of the heat dissipation cavity 125. In another embodiment, the floating component 130 is provided around the perimeter of the heat dissipation cavity 125 to enclose the heat dissipation cavity 125 in a closed space, which improves the stability of the heat dissipation apparatus, and also avoids flowing of the fluid out of the heat dissipation apparatus, thereby protecting the single board element 160 connected to the heat dissipation apparatus. It is to be noted that, in an embodiment, the first cooling plate 110 and the second cooling plate 120 are designed in a rectangular shape, and the heat dissipation cavity 125 is also designed in a rectangular shape, and the floating component 130 may be provided on one side of the rectangular cavity alone, and may also be provided on opposite sides of the rectangular cavity. In order to improve the stability of the heat dissipation apparatus, to avoid flowing of the fluid out of the heat dissipation apparatus, and to protect the single board element 160 connected to the heat dissipation apparatus, the floating component 130 is provided on the four edges of the rectangular cavity, to surround of the heat dissipation cavity 125. It is to be noted that the specific forms of the first cooling plate 110 and the second cooling plate 120 may be regular geometrical shapes or irregular geometrical shapes, and the rectangular shape is taken as an example for illustration in the accompanying drawings of embodiments of the present disclosure, which, however, is not meant to be a limitation of the present disclosure.

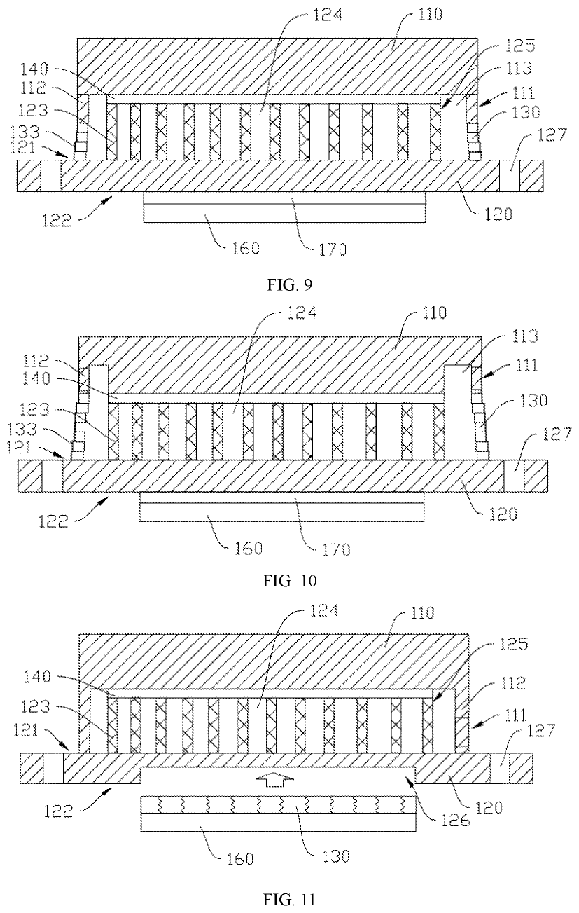

Referring to FIG. 9, in some embodiments of the present disclosure, the first cooling plate 110 is provided with a protruding portion 112, which is a structural form of the first cooling plate 110. In an embodiment, the protruding portion 112 and the first cooling plate 110 may be integrally molded and machined, while in another embodiment, the protruding portion 112 and the first cooling plate 110 may also be separately machined and assembled. According to the presence of the protruding portion 112, the first cooling plate 110 is provided with a first groove 113 at a position corresponding to the protruding portion 112, the through hole 111 is provided in the protruding portion 112 and the through hole 111 is at a position corresponding to a position of the first groove 113, and the protruding portion 112 has a certain length. In an embodiment, the protruding portion 112 is disposed on two sides of the first cooling plate 110, and the groove formed may be a portion recessed in the first cooling plate 110, as shown with reference to FIG. 10, or a portion between the first groove 113 and the heat dissipation teeth 123. Through the first groove 113, the fluid from the through hole 111 enters into the first groove 113 and into the heat dissipation cavity 125, and then passes through the flow channel 124 in the heat dissipation cavity 125 to reach and converge in the groove on the other side, which is in communication with the outside world through the through hole 111 and the outlet pipe 1112. The design of the flow channels 124 in the heat dissipation cavity 125 of the cooling plate improves the heat dissipation capability of the cooling plate, and according to the actual needs, the corresponding flow channels 124, such as milled channels, can be specially provided to satisfy the heat dissipation requirements, so as to place types such as spoilers or relieving teeth micro-channels, and the like, in order to ensure the heat dissipation and the circulation of fluid therefor, thereby improving the heat dissipation effect.

Referring to FIGS. 9 and 10, in some embodiments of the present disclosure, in the case where the floating component 130 is connected to the first cooling plate 110 and the second cooling plate 120 respectively, one end of the floating component 130 is connected to the protruding portion 112 on the first cooling plate 110 and the other end of the floating component 130 is connected to the first surface 121 of the second cooling plate 120, thus realizing a floating connection between the first cooling plate 110 and the second cooling plate 120. The heat dissipation cavity 125 is hermetically sealed by the floating component 130, which improves the stability of the heat dissipation apparatus and avoids flowing of the fluid out of the heat dissipation apparatus, thereby protecting the single board element 160 connected to the heat dissipation apparatus. It is to be noted that, in another embodiment, referring to FIG. 2, in the case where the floating component 130 is provided on the second surface 122 of the second cooling plate 120, the protruding portion 112 may be directly connected to the first surface 121 of the second cooling plate 120, and the heat dissipation cavity 125 is hermetically sealed by the protruding portion 112, which improves the stability of the heat dissipation apparatus and avoids flowing of the fluid out of the heat dissipation apparatus, thereby protecting the single board element 160 connected to the heat dissipation apparatus.

Referring to FIG. 11, in some embodiments of the present disclosure, in the case where the floating component 130 is provided on the second surface 122, the second cooling plate 120 is provided with a second groove 126 in the second surface 122, of which shape is matched with the shape of the floating component 130, the floating component 130 may be embedded in the second groove 126 so that when the floating component 130 does not need to be deformed or needs to be slightly deformed, the floating component 130 can be embedded in the second groove 126. The second surface 122 of the second cooling plate 120 is flat, so that when the floating component 130 needs to be deformed for stable connection with the single board element 160, one end of the floating component 130 may be fixedly connected to the second surface 122 of the second cooling plate 120, and the other end of the floating component 130 may be connected by retractable connection to the single board element 160 or the interface material 170. By providing the second groove 126, it is made possible that if the floating component 130 is provided on the second surface 122, the space of the heat dissipation apparatus is saved, and the extra space inside the device designed for heat dissipation is greatly reduced while ensuring a certain heat dissipation effect.

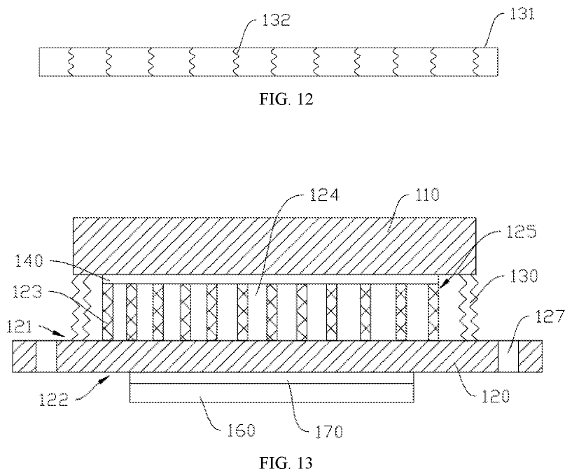

Referring to FIG. 12, in some embodiments of the present disclosure, the floating component 130 includes a retractable housing 131, an elastic element 132 provided in the housing 131. Two ends of the elastic element 132 are connected to two inner sides of the housing 131, respectively, and the housing 131 contains a large number of miniature springs or elastic sheets as the elastic element 132 therein, which miniature springs or elastic sheets 140 may be machined by conventional machining approaches or by new types of 3D printing and other technologies, and the embodiments of the present disclosure do not impose specific limitations thereon. While having the floating deformation characteristics, because the springs or elastic sheets are made of metal or graphite flakes or other high thermal conductivity materials, its thermal conductivity characteristics are good, and its inherent thermal resistance is small, thus improving the heat dissipation effect of the heat dissipation apparatus. The floating component 130 needs to be machined integrally, or in the manner of separate machining and assembling them together, which does not affect its floatability or retractability.

It is to be noted that in the case where the floating component 130 is provided on the second surface 122 of the second cooling plate 120, the floating component 130 includes a retractable housing 131, whereas in the case where the floating component 130 is provided between the first cooling plate 110 and the second cooling plate 120, the floating component 130 may be in a plate shape, or in a tube shape, and, with reference to FIG. 13, may be a corrugated plate, or in other shapes, or structures of different materials that have certain retractability.

Referring to FIGS. 9 and 10, in some embodiments of the present disclosure, the housing 131 is provided with a braided layer 133 on the outer surface thereof, where the braided layer 133 covers the housing 131, and the braided layer 133 may be made of a metal material or other materials, such as a carbon fiber, an organic polymer material, etc., and the embodiments of the present disclosure do not impose specific limitations thereon. In practice, the thickness of the floating component 130 may be specifically selected according to the retractable requirements of a specific scenario, resulting in varying strengths of the floating component 130, and by the provision of the braided layer 133, the strength of the floating component 130 can be improved, and the structure is made simple, thereby improving the stability of the heat dissipation apparatus.

In some embodiments of the present disclosure, in the case where the floating component 130 is connected to the first cooling plate 110 and the second cooling plate 120, for occasions with high reliability requirements, the connection may be in the form of welding, with one end of the floating component 130 being welded to the first cooling plate 110 and the other end of the floating component 130 being welded to the first surface 121, or for occasions with low reliability requirements, the connection may also be in the form of a medium or the like, the floating component 130 is provided with a first medium (not shown in the figures), with one end of the floating component 130 being connected to the first cooling plate 110 via the first medium, and the other end of the floating component 130 being connected to the first surface 121 via the first medium. In the case where the floating component 130 is provided on the second surface 122, for occasions with high reliability requirements, the connection may be in the form of welding, with the floating component 130 being welded to the second surface 122, or, for occasions with low reliability requirements, the connection may also be in the form of a medium or the like, the floating component 130 is provided with a second medium (not shown in the figure), with the floating component 130 being connected to the second surface 122 via the second medium. In an embodiment, different manners of connection are adopted for the floating component 130 for different reliability occasions, with welding being used for occasions with high reliability requirements, and connection being made through a first medium or a second medium for occasions with low reliability, where the first medium and the second medium may be made of a material for sealing connections, such as sealing rings, adhesives, or silicone. In another embodiment, the floating component 130 may also be connected to the first cooling plate 110 or the second cooling plate 120 by means of integral machining, the contact between the floating component 130 and the first cooling plate 110 or the second cooling plate 120 is realized by means of acting forces, and so on. In the embodiments of the present disclosure, different connecting manners may be applied specifically according to occasions with different reliability requirements, and the embodiments of the present disclosure do not impose specific limitations thereon.

In some embodiment of the present disclosure further provided is an electronic device. The electronic device may include the heat dissipation apparatus of any of the above embodiments, and the electronic device may be an ICT device or a device such as a battery heat dissipation system that requires heat dissipation. The electronic device may include an electronic element such as a single board element 160, a battery, or an optical module, and the single board element 160 is taken as an example for illustration in an embodiment of the present disclosure, which, however, is not meant to be a limitation of the present disclosure. The single board element 160 may be a single board or a chip, and the electronic device may also include an interface material 170 connected to the single board element 160, and the single board element 160 may be directly connected to the second surface 122 of the second cooling plate 120 of the heat dissipation apparatus, or the connection may also be realized through the interface material 170. By providing the retractable floating component 130 in the heat dissipation apparatus, heat dissipation may be realized by the heat dissipation cavity 125 formed between the first cooling plate 110 and the second cooling plate 120. It is to be noted that the floating component 130 may be disposed between the first cooling plate 110 and the second cooling plate 120 to adjust, by means of retraction, the distance between the first cooling plate 110 and the second cooling plate 120, and it may also be disposed correspondingly on the second surface 122 of the second cooling plate 120 to adjust, by means of retraction, the distance between the second cooling plate 120 and the single board element 160 connected to the heat dissipation apparatus. By means of the provision of the floating component 130, the electronic device in the embodiments of the present disclosure has good floatability and high reliability, and can be in stable contact with the heat dissipation apparatus to effectively cool down the electronic elements inside the electronic device, and the electronic device can also be applied in the design of the air-cooled whole-plate heat radiator and the design of the vapor chamber (VC).

According to the embodiments of the present disclosure, the heat dissipation apparatus has at least the following beneficial effects: in the heat dissipation apparatus in the embodiments of the present disclosure, by means of the provision of the retractable floating component, a heat dissipation cavity is formed between the first cooling plate and the second cooling plate, and by means of the floating component, according to the reaction force of the pipeline between the cooling plates due to the height difference and/or tolerance, the spacing between the second cooling plate and the first cooling plate or the spacing between the second cooling plate and the single board element is retractably adjusted, so as to ensure that the second cooling plate and the single board element always remain in reliable contact; therefore, the heat dissipation apparatus of the embodiments of the present disclosure has good floatability and high reliability, and is capable of making stable contact with an electronic element, such as a single board element, to effectively cool the electronic element.

It should also be understood that the various implementations provided by embodiments of the present disclosure may be combined in any combination to achieve different technical effects.

The above is a detailed description of some embodiments of the present disclosure. However, the present disclosure is not limited to the above-mentioned embodiments. Those of ordinary skill in the art can also make various equivalent modifications or replacements without departing from the principle of the present disclosure, and these equivalent modifications or replacements are all included in the scope defined by the claims of the present disclosure.

1. A heat dissipation apparatus, comprising:
a first cooling plate, provided with a through hole arranged to be connected to an inlet pipe and an outlet pipe;
a second cooling plate, with a heat dissipation cavity formed between the first cooling plate and the second cooling plate and in communication with the through hole; and
a retractable floating component, connected to the second cooling plate for floating heat dissipation of the second cooling plate.

2. The heat dissipation apparatus according to claim 1, wherein the floating component is connected to the first cooling plate and the second cooling plate, and arranged on at least one side of the heat dissipation cavity.

3. The heat dissipation apparatus according to claim 1, wherein the heat dissipation cavity is provided on a first surface of the second cooling plate, and the floating component is provided on a second surface of the second cooling plate opposite to the first surface.

4. The heat dissipation apparatus according to claim 1, wherein the second cooling plate is provided with heat dissipation teeth on a first surface of the second cooling plate in the dissipation cavity, and has flow channels formed between gaps of the heat dissipation teeth and in communication with the through hole.

5. The heat dissipation apparatus according to claim 1, wherein the first cooling plate is provided with a protruding portion, and a first groove in a position corresponding to the protruding portion, the through hole is provided in the protruding portion in a position corresponding to the first groove.

6. The heat dissipation apparatus according to claim 5, wherein one end of the floating component is connected to the protruding portion and the other end of the floating component is connected to a first surface of the second cooling plate.

7. The heat dissipation apparatus according to claim 1, wherein the floating component comprises a retractable housing, and an elastic element arranged in the housing, two ends of the elastic element are connected to two inner sides of the housing, respectively.

8. The heat dissipation apparatus according to claim 7, wherein the housing is provided with a braided layer on an outer surface of the housing.

9. The heat dissipation apparatus according to claim 2, wherein the floating component is provided surrounding the perimeter of the heat dissipation cavity.

10. The heat dissipation apparatus according to claim 2, wherein one end of the floating component is welded to the first cooling plate and the other end of the floating component is welded to the second cooling plate, or
the floating component is provided with a first medium, and one end of the floating component is connected to the first cooling plate through the first medium and the other end of the floating component is connected to the second cooling plate through the first medium.

11. The heat dissipation apparatus according to claim 3, wherein the second cooling plate is provided with a second groove in the second surface, in which the floating component is embedded.

12. The heat dissipation apparatus according to claim 3, wherein the floating component is welded to the second surface, or
the floating component is provided with a second medium through which the floating component is connected to the second surface.

13. The heat dissipation apparatus according to claim 4, further comprising a retractable elastic sheet, of which one end is connected to the heat dissipation teeth and the other end is connected to the first cooling plate.

14. An electronic device, comprising a heat dissipation apparatus, wherein the heat dissipation apparatus comprises:
a first cooling plate, provided with a through hole arranged to be connected to an inlet pipe and an outlet pipe;
a second cooling plate, with a heat dissipation cavity formed between the first cooling plate and the second cooling plate and in communication with the through hole; and
a retractable floating component, connected to the second cooling plate for floating heat dissipation of the second cooling plate.
